(19) United States
(12) Patent Application Publication
(10) Pub. No.: US 2012/0329252 A1
(43) Pub. Date: Dec. 27, 2012

(54) SEMICONDUCTOR DEVICE AND METHOD OF FABRICATING THE SAME

(75) Inventors: WonSeok Yoo, Hwaseong-si (KR); Nam-Kyu Kim, Yongin-si (KR); Bonghyun Kim, Incheon (KR); Seung Hun Lee, Seoul (KR); Heedon Hwang, Yongin-si (KR)

(73) Assignee: SAMSUNG ELECTRONICS CO., LTD., Suwon-si (KR)

(21) Appl. No.: 13/529,564

(22) Filed: Jun. 21, 2012

(30) Foreign Application Priority Data
Jun. 22, 2011 (KR) 10-2011-0060783

(51) Int. Cl. H01L 21/20

(52) U.S. Cl. 438/478; 257/E21.09

(57) ABSTRACT

A semiconductor device may include a semiconductor substrate with an active region, a gate line disposed on the active region, an epitaxial pattern disposed on the semiconductor substrate beside the gate line, the epitaxial pattern including a semiconductor material different from the semiconductor substrate, and a capping pattern disposed on the epitaxial pattern. The capping pattern may improve contact with contact plug and may reduce variation in mean ion depths of an associated field effect transistor.

### CROSS-REFERENCE TO RELATED APPLICATIONS

This U.S. non-provisional patent application claims priority under 35 U.S.C. §119 to Korean Patent Application No. 10-2011-0060783, filed on Jun. 22, 2011, in the Korean Intellectual Property Office, the entire contents of which are hereby incorporated by reference.

### BACKGROUND OF THE INVENTION

Exemplary embodiments in accordance with principles of inventive concepts relate generally to a semiconductor device. More particularly, exemplary embodiments in accordance with principles of inventive concepts relate to a semiconductor device including an embedded structure, such as an embedded silicon-germanium structure, and a method of fabricating the same.

Integrated circuits may include field-effect transistors (FET) that have a gate electrode serving as a control electrode and source and drain electrodes disposed at either sides of the gate electrode. The gate electrode may be used to control an energy level of a semiconductor region interposed between the source and drain electrodes (i.e., a channel region). That is, a channel current can be controlled by adjusting a gate voltage applied to the gate electrode in such devices.

Because the performance of a FET is strongly dependent on the mobility of majority carriers in the channel region, efforts have been made to increase channel-region carrier mobility. A structure that imposes a mechanical stress on the channel region of a FET may increase channel-region carrier mobility. For example, an embedded silicon-germanium (eSiGe) structure may improve performance of p-type metal-oxide-silicon (PMOS) FET. According to the eSiGe structure, a silicon-germanium layer may be provided adjacent to the channel region of the PMOS FET to exert a compressive stress on the channel region, thereby increasing the mobility of majority carriers of the PMOS FET (i.e., holes). However, the silicon-germanium layer formed using an epitaxial technique may have crystal facets that may lead to deterioration in dispersion characteristics of the transistor, or other defects, for example.

### SUMMARY

Exemplary embodiments in accordance with principles of inventive concepts provide a semiconductor device having high reliability.

According to exemplary embodiments in accordance with principles of inventive concepts, a method of fabricating a semiconductor device may include providing a semiconductor substrate with an active region, forming a gate line on the active region, etching the semiconductor substrate to form a recess region beside the gate line, forming an epitaxial pattern in the recess region, the epitaxial pattern including a semiconductor material different from that of the semiconductor substrate, and forming a capping pattern on the epitaxial pattern. The forming of the capping pattern may include a cyclic process of repeatedly and alternatingly performing deposition and etching steps.

In some exemplary embodiments in accordance with principles of inventive concepts, the method may further include cleaning the semiconductor substrate provided with the recess region, which may be performed after the etching of the semiconductor substrate. The cleaning of the semiconductor substrate may be performed using at least one of a wet chemical process or a plasma etching process.

In some exemplary embodiments in accordance with principles of inventive concepts, the capping pattern may include an undoped layer or a boron-doped layer. The boron doped layer may be formed using at least one of an ion implantation process, a plasma doping process, or an in-situ doping process.

In some exemplary embodiments in accordance with principles of inventive concepts, the forming of the capping pattern may be performed by alternatingly supplying a deposition source gas and an etching source gas.

In some exemplary embodiments in accordance with principles of inventive concepts, the deposition source may include at least one of monosilane (SiH₄), disilane (Si₂H₆), trisilane (Si₃H₈), tetrasilane (Si₄H₁₀), or dichlorosilane (SiH₂Cl₂), and the etching source may include at least one of hydrogen chloride (HCl) or chlorine (Cl2).

In some exemplary embodiments in accordance with principles of inventive concepts, the forming of the capping pattern may further include a purge step performed between the deposition step and the etching step. The purge step may be performed to pump out a residual gas used in the deposition and/or etching step from a process chamber.

In some exemplary embodiments in accordance with principles of inventive concepts, the capping pattern may be formed by performing a cyclic process including a deposition step, a purge step, an etching step, and another purge step, one or more times.

According to exemplary embodiments in accordance with principles of inventive concepts, a semiconductor device may include a semiconductor substrate with an active region, a gate line disposed on the active region, an epitaxial pattern disposed on the semiconductor substrate beside the gate line, the epitaxial pattern having a bottom surface lower than that of the gate line and including a semiconductor material different from the semiconductor substrate, and a capping pattern disposed on the epitaxial pattern. The capping pattern may include at least one crystal surface having a crystallographic orientation different from (100) and (110).

In some exemplary embodiments in accordance with principles of inventive concepts, the capping pattern may include a crystal surface having at least one of (100), (110), (111) or (311) crystallographic orientations.

In some exemplary embodiments in accordance with principles of inventive concepts, the epitaxial pattern may include silicon-germanium (SiGe) or silicon carbide (SiC).

In some exemplary embodiments in accordance with principles of inventive concepts, the capping pattern may include at least one of the same element as that of the semiconductor substrate and the same element as that of the epitaxial pattern.

In exemplary embodiments in accordance with principles of inventive concepts a semiconductor device, such as a field effect transistor may be faulted by providing a semiconductor substrate with an active region; forming a gate line on the active region; forming recess regions beside and on either side of the gate line; forming an epitaxial pattern in the recess regions, the epitaxial pattern including a semiconductor material different from that of the semiconductor substrate; and forming a capping pattern on the epitaxial pattern, wherein the capping pattern has better contact characteristics than the contact characteristics of the epitaxial pattern.

The top surface of a capping pattern in accordance with principles of inventive concepts may be flatter than the top surface of an epitaxial layer, thereby providing better contact characteristics for a contact plug.

The top surface of a capping pattern in accordance with principles of inventive concepts may include a region of lesser slope than the top surface of an underlying sloped epitaxial layer, thereby providing better contact characteristics for a contact plug.

A capping layer in accordance with principles of inventive concepts may exhibit lower contact resistance than an underlying epitaxial layer, for example, by including a metal silicide layer.

A capping layer in accordance with principles of inventive concepts may reduce variation in the mean ion depth in an associated field effect transistor.

### BRIEF DESCRIPTION OF THE DRAWINGS

Exemplary embodiments in accordance with principles of inventive concepts will be more clearly understood from the following brief description taken in conjunction with the accompanying drawings. The accompanying drawings represent non-limiting, exemplary embodiments as described herein.

FIGS. 1 through 5A are sectional views illustrating a semiconductor device and a method of fabricating the same according to exemplary embodiments in accordance with principles of inventive concepts;

FIGS. 5B and 5C are enlarged sectional views of a portion of FIG. 5A;

FIG. 6A are sectional views illustrating a semiconductor device and a method of fabricating the same according to exemplary embodiments in accordance with principles of inventive concepts; and

FIG. 6B is an enlarged sectional view of a portion of FIG. 6A.

It should be noted that these figures are intended to illustrate the general characteristics of methods, structure and/or materials utilized in certain exemplary embodiments and to supplement the written description provided below. These drawings are not, however, to scale and may not precisely reflect the precise structural or performance characteristics of any given embodiment, and should not be interpreted as defining or limiting the range of values or properties encompassed by exemplary embodiments. For example, the relative thicknesses and positioning of molecules, layers, regions and/or structural elements may be reduced or exaggerated for clarity.

### DETAILED DESCRIPTION

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, semiconductor devices and methods of fabricating the same according to exemplary embodiments in accordance with principles of inventive concepts will now be described more fully with reference to the accompanying drawings.

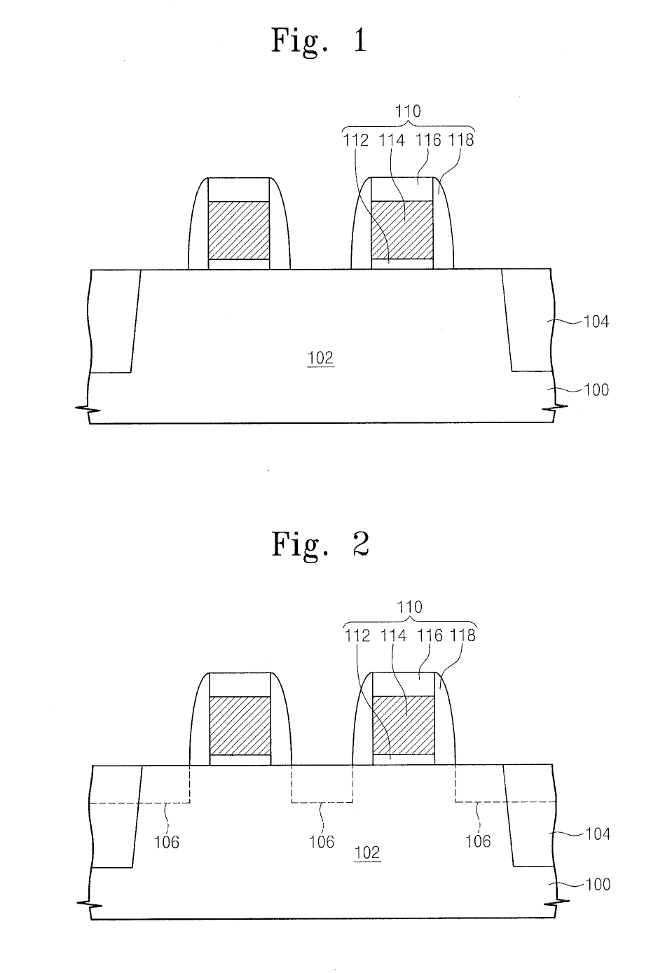

FIGS. 1 through 5A are sectional views illustrating methods of fabricating a semiconductor device according to some embodiments of the inventive concepts.

Referring to FIG. 1, a semiconductor substrate 100 including an active region 102 may be provided. In the semiconductor substrate 100, a device isolation pattern 104 may be provided to surround active region 102.

Semiconductor substrate 100 may include a single crystalline semiconductor material. For example, semiconductor substrate 100 may be a silicon substrate or a germanium substrate, but exemplary embodiments in accordance with principles of inventive concepts may not be limited thereto.

Active region 102 may be defined by forming a trench in semiconductor substrate 100. Device isolation pattern 104 may be locally formed in a trench to confine active region 102. Active region 102 may be doped with impurities of a first conductivity type, for example. In some exemplary embodiments, semiconductor substrate 100 may include a well region of the first conductivity type, which may be overlapped with active region 102.

Device isolation pattern 104 may be formed in the well region. Device isolation pattern 104 may be formed of an insulating material, for example. In some exemplary embodiments, device isolation pattern 104 may be formed to have a shallow-trench isolation (STI) structure. In such exemplary embodiments, as described above, the formation of device isolation pattern 104 may include forming the trench in the semiconductor substrate 100 and then filling the trench with an insulating material.

A gate insulating layer 112, a gate electrode 114, and a gate capping pattern 116 may be sequentially stacked on semiconductor substrate 100.

Gate insulating layer 112 may include at least one of an oxide layer (e.g., a thermal oxide layer), a nitride layer, an oxynitride layer, and/or a high-k dielectric (e.g., metal oxides, such as aluminum oxide or hafnium oxide), for example. Gate electrode 114 may include at least one of a doped semiconductor layer (e.g., of doped silicon or doped germanium), a metal layer (e.g., of tungsten, titanium, or tantalum), a conductive metal nitride layer (e.g., of titanium nitride, tantalum nitride, or tungsten nitride), or a metal-semiconductor compound (e.g., of tungsten silicide or cobalt silicide), for example. Gate capping pattern 116 may include at least one layer of oxide, nitride, and/or oxynitride, for example.

A spacer layer 118 may be formed on both sidewalls of gate electrode 114. The formation of spacer layer 118 may include forming an insulating layer on a structure with gate electrode 114 and then anisotropically etching the insulating layer. Spacer layer 118 may include at least one layer of oxide, nitride, and/or oxynitride. In some exemplary embodiments, gate insulating layer 112, gate electrode 114, gate capping pattern 116, and spacer layer 118 may substantially constitute a gate line 110.

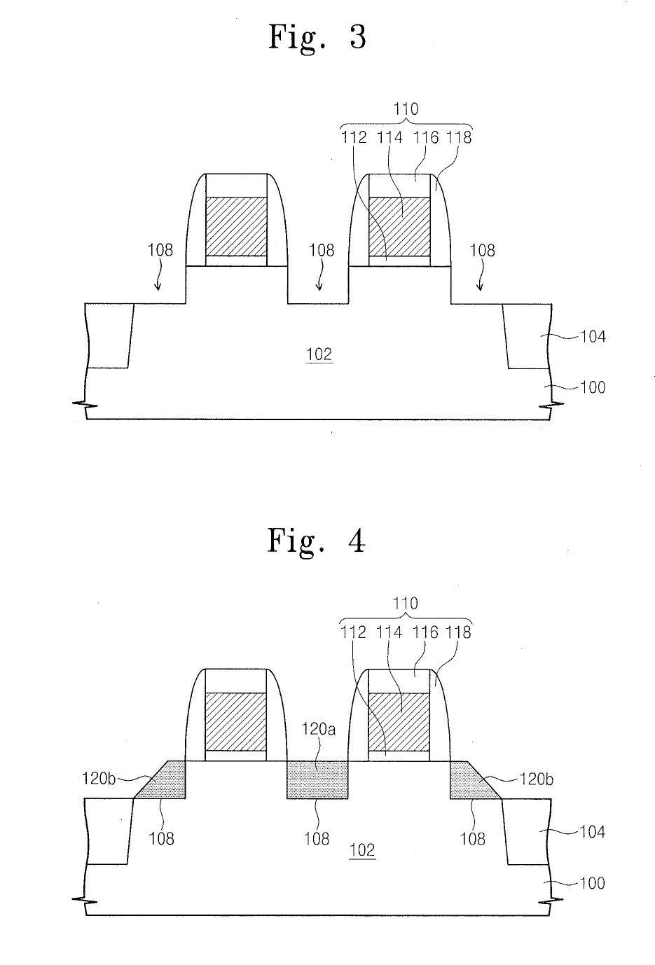

Referring to FIGS. 2 and 3, semiconductor substrate 100 may be etched to form a recessed region 108. In some exemplary embodiments, the formation of recessed region 108 may include etching semiconductor substrate 100 using gate line 110 as an etch mask. As a result, some regions 106 of active region 102, positioned at both sides of gate line 110, may be etched to form recessed regions 108. In some embodiments, the etching of active region 102 may be performed using an anisotropic or isotropic etching process, or combination thereof.

In some exemplary embodiments, a cleaning process may be performed on semiconductor substrate 100, after the formation of recessed region 108. The cleaning process may be performed using a wet chemical or a plasma, for example.

In some exemplary embodiments, a vertical section of recess region 108 may be shaped like a polygon having four or more edges. Recess region 108 may have three or more inner surfaces exposing active region 104. At least one of the inner surfaces defining recess region 108 may be formed to have a (111) crystallographic orientation.

In some exemplary embodiments, recess region 108 may have an un-doped bottom surface. The bottom surface of recess region 108 may be formed at a higher level than a bottom surface of device isolation pattern 104, for example.

In some embodiments, during the etching of the active region 102, device isolation pattern 104 may be etched along with active region 102. As a result, device isolation pattern 104 may have a recessed top surface. For example, the top surface of device isolation pattern 104 may be formed at the same level as or a higher level than the bottom surface of recess region 108.

Referring to FIG. 4, first and second epitaxial patterns 120a and 120b may be formed in recess regions 108. In some exemplary embodiments, first and second epitaxial patterns 120a and 120b may serve as source and drain electrodes of a field effect transistor, respectively.

First and second epitaxial patterns 120a and 120b may be formed using a selective epitaxial process, for example.

First and second epitaxial patterns 120a and 120b may include semiconductor material different from that of semiconductor substrate 100, for example. As a result, a compressive force or a tensile force may be exerted upon a portion of active region 102 under gate lines 110 (i.e., a channel region of MOSFET), stemming from a difference in lattice constant between semiconductor substrate 100 and first and second epitaxial patterns 120a and 120b. The compressive or tensile force may contribute to increased carrier mobility at the channel region during operation of field effect transistor.

In some exemplary embodiments, first and second epitaxial patterns 120a and 120b may be configured to exert a compressive force on the channel region of a PMOS transistor. Due to the compressive force exerted on the channel region, the PMOS transistor may have an improved hole mobility property. To exert the compressive force on the channel region, the first and second epitaxial patterns 120a and 120b may include a semiconductor material having a lattice constant greater than that of semiconductor substrate 100. For example, in a case where semiconductor substrate 100 is formed of silicon, first and second epitaxial patterns 120a and 120b may be formed of silicon-germanium or germanium.

In some exemplary embodiments, first and second epitaxial patterns 120a and 120b may be configured to exert a tensile force on the channel region of NMOS transistor. Due to the tensile force exerted on the channel region, the NMOS transistor may have an improved electron mobility property. To exert the tensile force on the channel region, first and second epitaxial patterns 120a and 120b may include a semiconductor material having a lattice constant smaller than that of semiconductor substrate 100. For example, in a case where semiconductor substrate 100 is formed of silicon, first and second epitaxial patterns 120a and 120b may be formed of silicon carbide (SiC).

In some exemplary embodiments, first and second epitaxial patterns 120a and 120b may be wholly doped with impurities of a second conductivity type. In a case where the field effect transistor is a PMOS transistor, the first conductivity type may be n-type, and the second conductivity type may be p-type. Alternatively, in a case where the field effect transistor is an NMOS transistor, the first conductivity type may be p-type, and the second conductivity type may be n-type. First and second epitaxial patterns 120a and 120b may be doped in an in-situ process, for example.

First and second epitaxial patterns 120a and 120b may be formed to fill recess region 108 wholly and may be in contact with recess region 108. In some exemplary embodiments, epitaxial patterns 120a and 120b may be formed to have top surfaces higher than or equivalent to a top surface of active region 102.

First epitaxial pattern 120a may be formed between gate lines 110, for example. The bottom surface and both side surfaces of recess region 108 may be used as a seed layer for growing first epitaxial pattern 120a during a selective epitaxial process. In some exemplary embodiments, first epitaxial pattern 120a may be concurrently grown from the bottom surface and both side surfaces of recess region 108. Epitaxial pattern 120a may be grown to have a substantially flat top surface, for example.

Second epitaxial pattern 120b may be formed between gate lines 110 and device isolation pattern 104. The bottom surface of recess region 108 and one side surface of recess region 108, adjacent to spacer layer 118, may be used as a seed layer for growing first epitaxial pattern 120a, during a selective epitaxial process.

As a result, second epitaxial pattern 120b may be asymmetrically grown to have an uneven top surface. For example, second epitaxial pattern 120b may be formed to have a sloped sidewall adjacent to device isolation pattern 104, and second epitaxial pattern 120b may have a tetragonal or trapezoidal section having the top side shorter than the bottom side, for example.

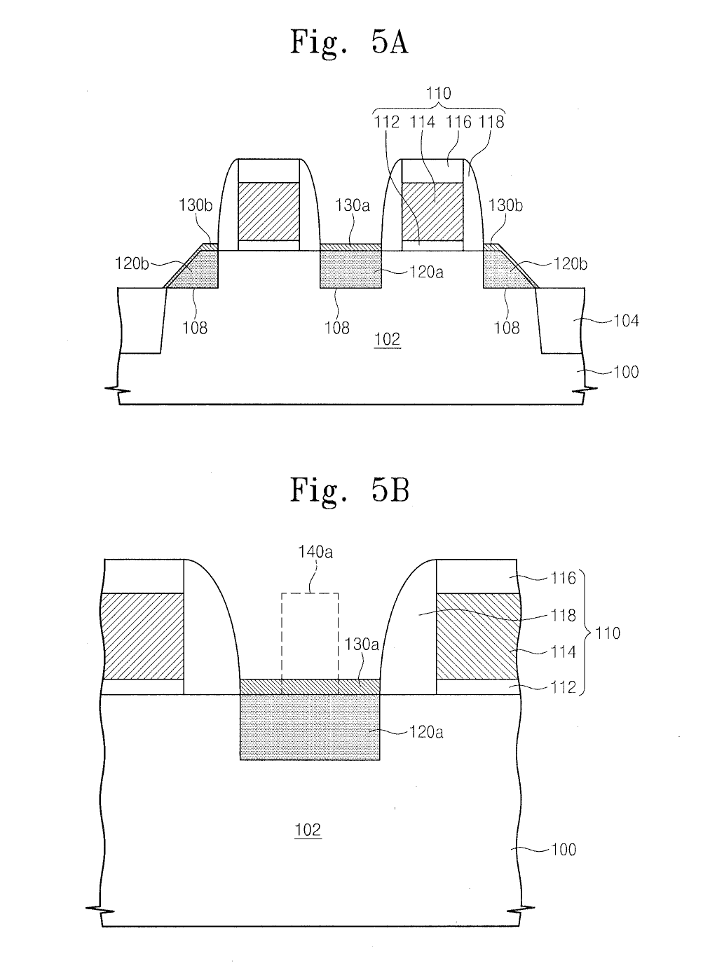

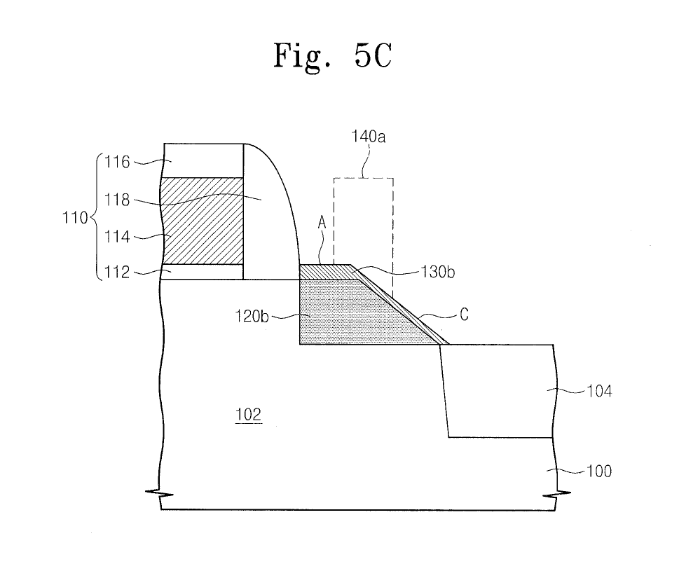

Referring to FIG. 5A, first and second capping patterns 130a and 130b may be formed on first and second epitaxial patterns 120a and 120b, respectively.

First and second capping patterns 130a and 130b may be formed to be in contact with top surfaces of first and second epitaxial patterns 120a and 120b, respectively, and may also be in contact with source and drain regions of the field effect transistor.

First and second capping patterns 130a and 130b may be formed of the same material as the semiconductor substrate 100 or as the first and second epitaxial patterns 120a and 120b. For example, first and second capping patterns 130a and 130b may be formed of a silicon layer or a silicon-germanium layer. Alternatively, first and second capping patterns 130a and 130b may have a bi-layered structure including a silicon-germanium layer and a silicon layer, for example.

In some embodiments, first and second capping patterns 130a and 130b may be doped with atoms different from those of first and second epitaxial patterns 120a and 120b. For example, in a case where first and second epitaxial patterns 120a and 120b are formed of silicon-germanium, first and second capping patterns 130a and 130b may be formed of a lightly doped germanium containing layer and a heavily doped boron containing layer. The formation of a boron containing layer may be performed using an ion implantation process, a plasma doping process, or an in-situ doping process, for example. Due to the presence of first and second capping patterns 130a and 130b, first and second epitaxial patterns 120a and 120b can be connected to contact plugs disposed thereon with a low contact resistance.

In some embodiments, a metal silicide (not shown) may be formed on first and second capping patterns 130a and 130b. The formation of the metal silicide may include forming a metal layer on a structure including first and second capping patterns 130a and 130b and then reacting the metal layer with semiconductor atoms of first and second capping patterns 130a and 130b.

FIGS. 5B and 5C are enlarged sectional views of a portion of FIG. 5A.

Referring to FIG. 5B, first epitaxial pattern 120a may be formed to have a flat top surface, and the first capping pattern 130a may be formed to cover the entire top surface of the first epitaxial pattern 120a, for example. As a result, a contact plug 140a can be vertically formed on first capping pattern 130a having a flat top surface, with contact plug 140a having a flat bottom surface. The flat surface interface between contact plug 140a and capping pattern 130a may prevent a contact failure from occurring during a contact plug forming process.

Referring to FIG. 5C, second epitaxial pattern 120b may be formed to have an uneven top surface, unlike the case of the first epitaxial pattern 120a.

In an epitaxial process, a growth rate of an epitaxial layer may vary according to a crystallographic orientation of a surface used for a seed layer. For example, an epitaxial layer may be grown with the highest growth rate on a surface of (100) crystallographic orientation and with the lowest growth rate on a surface of (111) crystallographic orientation. As a result, the second epitaxial pattern 120b may be formed to have the surface C of (111) crystallographic orientation and be shaped like a trapezoid having the top side shorter than the bottom side. Since the second capping pattern 130b is formed on the second epitaxial pattern 120b, it may, as a result, have a substantially uneven top surface.

In some exemplary embodiments, second capping pattern 130b may be formed by performing deposition and etching steps in a continuous manner. For example, the formation of second capping pattern 130b may include supplying both of a dichlorosilane (SiH₂Cl₂) gas as a deposition source gas and a hydrogen chloride (HCl) gas as an etching gas into a process chamber. In such a process, second capping pattern 130b may be grown significantly faster on a surface A of (100) crystallographic orientation of second epitaxial pattern 120b than on surface C of (111) crystallographic orientation.

In a case where second capping pattern 130b is formed to have an uneven top surface, a contact failure may occur. For example, if a misalignment occurs in a lithography process for forming contact plug 140a, the (111) surface C of second capping pattern 130b may be etched. This may lead to an increase in a mean depth of ions (i.e., projection range, Rp) to be implanted in a subsequent ion implantation process. That is, the mean depth of implanted ions may be dependent on a degree of misalignment determined in the lithography process, and this may deteriorate dispersion characteristics of the transistor.

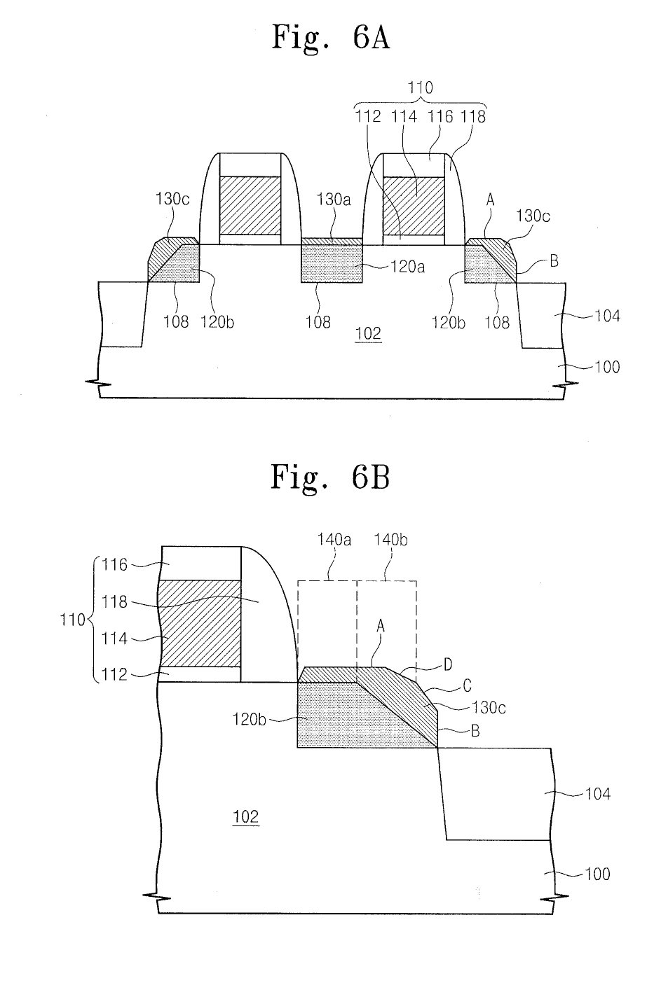

FIG. 6A is a sectional view illustrating a semiconductor device and a method of fabricating the same according to other exemplary embodiments in accordance with principles of inventive concepts, and FIG. 6B is an enlarged sectional view of a portion of FIG. 6A.

Referring to FIG. 6A, a third capping pattern 130c may be formed on second epitaxial pattern 120b between gate line 110 and device isolation pattern 104.

Third capping pattern 130c may be formed by a cyclic growth method, for example. In some exemplary embodiments, as the result of a cyclic growth method, second capping pattern 130b may be transformed into third capping pattern 130c or may serve as a portion of third capping pattern 130c.

The cyclic growth method may include repeatedly and alternatingly performing deposition and etching steps. For example, the cyclic growth method may include repeatedly and alternatingly supplying a deposition source gas and an etching source gas into a process chamber. A deposition source may include at least one of monosilane (SiH₄), disilane (Si₂H₆), trisilane (Si₃H₈), tetrasilane (Si₄H₁₀), or dichlorosilane (SiH₂Cl₂), for example. An etching source may include at least one of hydrogen chloride (HCl) or chlorine (Cl₂), for example.

A deposition step may be performed using at least one of an epitaxial process, an LPCVD process, or a PVD process, for example. An etching step may be performed using at least one of a dry etching method, a wet etching method, or a combined etching method including dry and wet etching processes, for example.

In some exemplary embodiments, the formation of third capping pattern 130c may include alternatingly supplying a dichlorosilane (SiH₂Cl₂) gas as a deposition source gas and a hydrogen chloride (HCl) gas as an etching gas into a process chamber. In other exemplary embodiments, the formation of third capping pattern 130c may include alternatingly supplying a monosilane (SiH₄) gas as a deposition source gas and a chlorine (Cl₂) gas as an etching gas into a process chamber, while a hydrogen (H₂) gas may be continuously supplied into the process chamber.

In some exemplary embodiments, a cyclic growth method may further include a purge step, which may be performed between deposition and etching steps. A purge step may be performed to pump out a residual gas from the process chamber, after a deposition step and/or etching step.

In some exemplary embodiments, the formation of third capping pattern 130c may include a cyclic process including a deposition step, a purge step, an etching step, and another purge step, performed in a cyclic manner. In other exemplary embodiments, the formation of third capping pattern 130c may include performing a cyclic process one or more times, for example.

Referring to FIG. 6B, third capping pattern 130c may have a polygonal section having four or more edges. Third capping pattern 130c may be formed to have two or more crystal faces. For example, third capping pattern 130c may include crystal faces A and B of (100) and (110) crystallographic orientations and additional crystal faces connecting the crystal faces A and B. The additional crystal faces may be formed to have a crystallographic orientation different from (100) and (110).

A growth rate of a deposition layer may vary according to a crystallographic orientation of an underlying layer. Third capping pattern 130c may be formed to have a surface A of (100) crystallographic orientation and a surface C of (111) crystallographic orientation.

An atomic bonding may be broken out during an etching step, and a surface of (110) crystallographic orientation may be the highest among exposed crystal surfaces in the number of dangling bonds. As a result, the surface of (110) crystallographic orientation may be etched faster than other surfaces and third capping pattern 130c may have a surface B of (110) crystallographic orientation.

In a case where deposition and etching steps are performed in an alternating manner, third capping pattern 130c may have at least one crystal surface having a crystallographic orientation different from (100) and (110). For example, third capping pattern 130c may be formed to have surfaces or facets A, B, C and D, whose crystallographic orientations are (100), (110), (111) and (311), respectively.

A semiconductor device according to exemplary embodiments of the inventive concepts may include third capping pattern 130c having surfaces of (100) and (110) crystallographic orientations and at least one surface having a crystallographic orientation different therefrom. As a result, third capping pattern 130c may have an increased thickness on a sloped surface of second epitaxial pattern 120b, compared to that of second capping pattern 130b shown in FIG. 5C. Such an increase in thickness may prevent contact failure between contact plugs 140a and 140b and source/drain electrodes of a MOSFET associated with gate line 110. Additionally, such increased thickness may reduce a variation in a mean depth of ions (i.e., projection range, Rp), thereby preventing the deterioration of dispersion characteristics of such a transistor.

According to exemplary embodiments of inventive concepts, a semiconductor device may include an epitaxial pattern and a capping pattern formed on the epitaxial pattern. The capping pattern may be formed to have crystal surfaces of (100) and (110) crystallographic orientations and at least one crystal surface having a crystallographic orientation different therefrom.

The capping pattern may be formed by a cyclic process including deposition and etching steps, which are performed in a cyclic manner. As a result, the capping pattern can be formed to have crystal surfaces of (100) and (110) crystallographic orientations and at least one crystal surface having a crystallographic orientation different therefrom, as described above. As a result, the capping pattern may be expanded in volume and/or area, thereby preventing contact failure between the contact plugs and source/drain electrodes of a MOSFET. Additionally, the variation in mean depth of ions (i.e., projection range, Rp) may be reduced, thereby preventing deterioration in dispersion characteristics of the transistor.

While exemplary embodiments of the inventive concepts have been particularly shown and described, it will be understood by one of ordinary skill in the art that variations in faun and detail may be made therein without departing from the spirit and scope of the attached claims.

1. A method of fabricating a semiconductor device, comprising:
providing a semiconductor substrate with an active region;
forming a gate line on the active region;
etching the semiconductor substrate to form a recess region beside the gate line;
forming an epitaxial pattern in the recess region, the epitaxial pattern including a semiconductor material different from that of the semiconductor substrate; and
forming a capping pattern on the epitaxial pattern, wherein the capping pattern has better contact characteristics than the contact characteristics of the epitaxial pattern.

2. The method of claim 1, wherein the foaming of the capping pattern comprises a cyclic process of repeatedly and alternatingly performing deposition and etching steps.

3. The method of claim 2, further comprising, after the etching of the semiconductor substrate, cleaning the semiconductor substrate provided with the recess region,
wherein the cleaning of the semiconductor substrate is performed using at least one of a wet chemical process or a plasma etching process.

4. The method of claim 2, wherein the capping pattern comprises an undoped layer or a boron-doped layer, and the boron doped layer is foamed using at least one of an ion implantation process, a plasma doping process, or an in-situ doping process.

5. The method of claim 2, wherein the foil ling of the capping pattern is performed by alternatingly supplying a deposition source gas and an etching source gas.

6. The method of claim 5, wherein the deposition source comprises at least one of monosilane (SiH₄), disilane (Si₂H₆), trisilane (Si₃H₈), tetrasilane (Si₄H₁₀), or dichlorosilane (SiH₂Cl₂), and the etching source comprises at least one of hydrogen chloride (HCl) or chlorine (Cl2).

7. The method of claim 2, wherein the forming of the capping pattern further comprises a purge step performed between the deposition step and the etching step, and
the purge step is performed to pump out a residual gas used in the deposition and/or etching step from a process chamber.

8. The method of claim 7, wherein the capping pattern is formed by performing a cyclic process including a deposition step, a purge step, an etching step, and another purge step, one or more times.

9-13. (canceled)

14. A method of fabricating a semiconductor device, comprising:
providing a semiconductor substrate with an active region;
forming a gate line on the active region;
forming recess regions beside and on either side of the gate line;
forming an epitaxial pattern in the recess regions, the epitaxial pattern including a semiconductor material different from that of the semiconductor substrate; and
forming a capping pattern on the epitaxial pattern, wherein the capping pattern has better contact characteristics than the contact characteristics of the epitaxial pattern.

15. The method of claim 14, including the step of forming the top surface of the capping layer to be flatter than the top surface of the epitaxial layer.

16. The method of claim 14, including the step of forming the capping layer to have a region of lesser slope than an underlying sloped epitaxial region.

17. The method of claim 14, including the step of forming the capping layer to have a lower contact resistance than an underlying epitaxial region.

18. The method of claim 17, wherein the step of forming the capping layer to have a lower contact resistance than an underlying epitaxial region includes forming a metal silicide layer on the capping layer.

19. The method of claim 14 further comprising the step of forming the capping layer to create a reduced variation in the mean ion depth in an associated field effect transistor.

20. The method of claim 14 wherein the step of foil ling a capping layer includes forming a capping layer having a region with a top surface of multiple facets.
